(19) United States
(12) Patent Application Publication
(10) Pub. No.: US 2025/0014981 A1
(43) Pub. Date: Jan. 9, 2025

(54) SEMICONDUCTOR DEVICE

(71) Applicant: FUJI ELECTRIC CO., LTD., Kawasaki-shi (JP)

(72) Inventor: Kensuke MATSUZAWA, Matsumoto-city (JP)

(73) Assignee: FUJI ELECTRIC CO., LTD., Kawasaki-shi (JP)

(21) Appl. No.: 18/675,337

(22) Filed: May 28, 2024

(30) Foreign Application Priority Data
Jul. 4, 2023 (JP) 2023-109827

(51) Int. Cl. H01L 23/498; H01L 23/00; H01L 23/31; H01L 23/544; H01L 25/065

(52) U.S. Cl. CPC H01L 23/49838; H01L 23/3121; H01L 23/544; H01L 24/40; H01L 24/48; H01L 24/49; H01L 24/73; H01L 25/0655; H01L 2223/54426; H01L 2224/40137; H01L 2224/40225; H01L 2224/48225; H01L 2224/4903; H01L 2224/73221; H01L 2924/1815

(57) ABSTRACT

A semiconductor device includes: an insulated circuit substrate including an insulating plate and a conductive plate provided on a top surface side of the insulating plate; a semiconductor chip provided on a top surface side of the conductive plate; a first external terminal electrically connected to the semiconductor chip; a first insulating member including a covering part covering a part of the first external terminal and a first engagement part provided on a top surface side of the covering part; a second external terminal provided on a top surface side of the first external terminal with the covering part interposed, and including a second engagement part so as to engage with the first engagement part; and a sealing resin provided to seal the semiconductor chip and partly seal each of the first external terminal, the first insulating member, and the second external terminal.

### CROSS-REFERENCE TO RELATED APPLICATION

This application claims benefit of priority under 35 USC 119 based on Japanese Patent Application No. 2023-109827 filed on Jul. 4, 2023, the entire contents of which are incorporated by reference herein.

### BACKGROUND OF THE INVENTION

### 1. Field of the Invention

The present disclosure relates to semiconductor devices (power semiconductor modules).

### 2. Description of the Related Art

US2020/0105707A1 discloses a semiconductor device package including a retaining tape for fixing each clip.

Research on adjacent arrangement (lamination arrangement) of a plurality of terminals in conventional power semiconductor modules has been promoted in order to reduce wire inductance.

However, conventional power semiconductor modules still do not have a configuration enough to ensure positioning accuracy for the plural terminals because of tolerance of assembly of the power semiconductor modules.

### SUMMARY OF THE INVENTION

In view of the foregoing problems, the present disclosure provides a semiconductor device including a plurality of terminals arranged adjacent to each other with a configuration capable of ensuring accuracy of positioning the respective terminals.

An aspect of the present invention inheres in a semiconductor device including: an insulated circuit substrate including an insulating plate and a conductive plate provided on a top surface side of the insulating plate; a semiconductor chip provided on a top surface side of the conductive plate; a first external terminal electrically connected to the semiconductor chip; a first insulating member including a covering part covering a part of the first external terminal and a first engagement part provided on a top surface side of the covering part; a second external terminal electrically connected to the semiconductor chip, provided on a top surface side of the first external terminal with the covering part interposed, and including a second engagement part so as to engage with the first engagement part; and a sealing resin provided to seal the semiconductor chip and partly seal each of the first external terminal, the first insulating member, and the second external terminal.

In the aspect of the present invention, the first engagement part may be a projecting part; and the second engagement part may be a recessed part.

In the aspect of the present invention, the first engagement part and the second engagement part may be covered with the sealing resin.

In the aspect of the present invention, the first insulating member may include a frame part surrounding a part of a side surface of the second external terminal.

In the aspect of the present invention, the semiconductor device may further include: a third external terminal electrically connected to the semiconductor chip and arranged separately from the first external terminal and the second external terminal; and a second insulating member provided to cover a part of the third external terminal.

In the aspect of the present invention, the semiconductor device may further include a third insulating member provided between the first insulating member and the second insulating member so as to be integrated together.

In the aspect of the present invention, the semiconductor device may further include a control terminal electrically connected to the semiconductor chip, wherein the third insulating member has an opening for positioning the control terminal.

In the aspect of the present invention, the covering part may be provided with a slit on the top surface side.

In the aspect of the present invention, the second insulating member may be provided with a fixing part for fixing the second external terminal.

It should be noted that the above summary of the invention does not list all the necessary features of the present invention. Subcombinations of these feature groups can also be inventions.

### BRIEF DESCRIPTION OF THE DRAWINGS

FIG. 1 is a perspective view illustrating a semiconductor device according to a first embodiment;

FIG. 2 is a plan view illustrating the semiconductor device according to the first embodiment;

FIG. 3 is a perspective view illustrating the semiconductor device according to the first embodiment;

FIG. 4 is a plan view illustrating the semiconductor device according to the first embodiment

FIG. 5 is a perspective view illustrating components included in the semiconductor device according to the first embodiment;

FIG. 6 is a plan view illustrating components included in the semiconductor device according to the first embodiment;

FIG. 7 is a perspective view illustrating components included in the semiconductor device according to the first embodiment;

FIG. 8 is a perspective view illustrating components included in the semiconductor device according to the first embodiment;

FIG. 9 is a perspective view illustrating components included in the semiconductor device according to the first embodiment;

FIG. 10 is a perspective view illustrating components included in the semiconductor device according to the first embodiment;

FIG. 11 is a side view illustrating the semiconductor device according to the first embodiment;

FIG. 12 is a side view illustrating the semiconductor device according to the first embodiment;

FIG. 13 is a side view illustrating a packaged structure of the semiconductor device according to the first embodiment;

FIG. 14 is an equivalent circuit diagram of the semiconductor device according to the first embodiment;

FIG. 15 is a plan view illustrating a semiconductor device according to a second embodiment; and

FIG. 16 is a plan view illustrating a semiconductor device according to a third embodiment.

### DETAILED DESCRIPTION

With reference to the drawings, first to third embodiments of the present disclosure will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

Additionally, definitions of directions such as “upper”, “lower”, “upper and lower”, “left”, “right”, and “left and right” in the following description are simply definitions for convenience of description, and do not limit the technological concept of the present disclosure. For example, when observing an object rotated by 90°, the “upper and lower” are converted to “left and right” to be read, and when observing an object rotated by 180°, the “upper and lower” are read reversed, which should go without saying. In addition, an “upper surface” and a “lower surface”, respectively, may be read as “front surface” and “back surface”. In addition, the “first main surface” and the “second main surface” of each member are main surfaces facing each other. For example, if the “first main surface” is the upper surface, the “second main surface” is the lower surface. In addition, the “first main surface” and the “second main surface”, respectively, may be read as “one of the main surfaces” and “the other one of the main surfaces”.

### First Embodiment

### <Structure of Semiconductor Device>

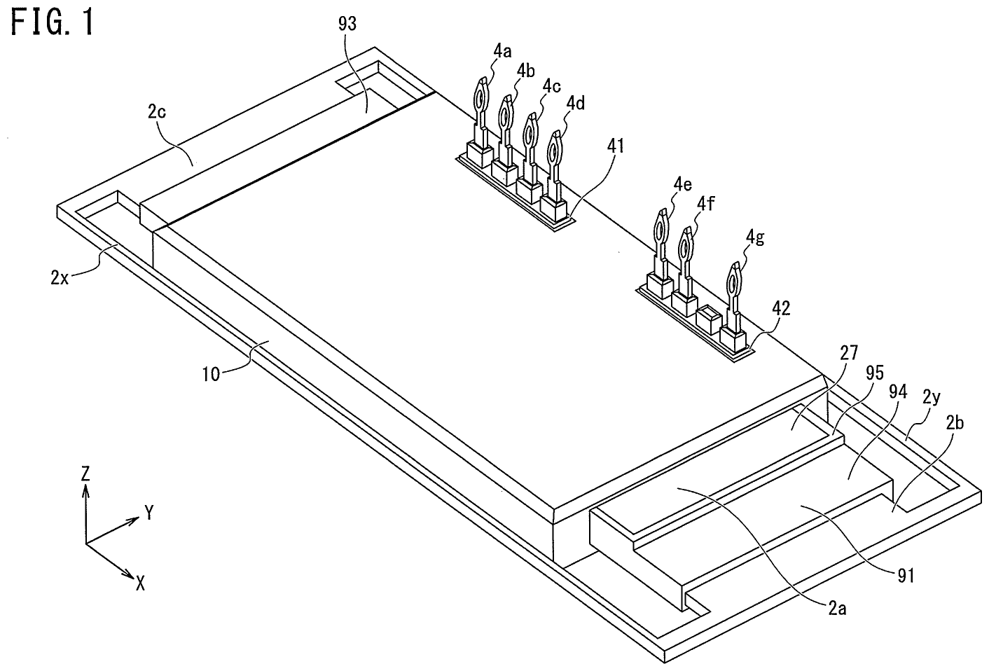

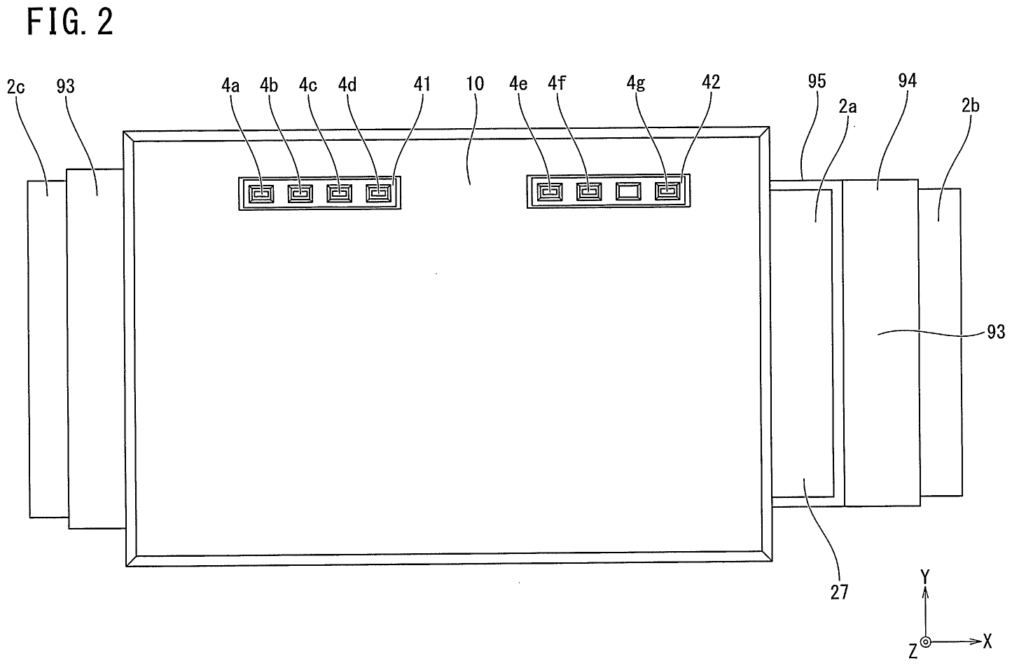

FIG. 1 is a perspective view illustrating a semiconductor device (a power semiconductor module) according to a first embodiment, and FIG. 2 is a plan view illustrating the semiconductor device according to the first embodiment. As illustrated in FIG. 1 and FIG. 2, the semiconductor device according to the first embodiment includes an external terminal (a negative electrode terminal) 2a, an external terminal (a positive electrode terminal) 2b, an external terminal (an output terminal) 2c, external terminals (control terminals) 4a to 4g, and a sealing resin 10 provided to seal semiconductor chips (not illustrated) and partly seal the negative electrode terminal 2a, the positive electrode terminal 2b, the output terminal 2c, and the control terminals 4a to 4g.

FIG. 1 illustrates the semiconductor device according to the first embodiment in a state during assembly, in which the positive electrode terminal 2b and the output terminal 2c are provided integrally with tie-bar wires 2x and 2y, which are metallic wires. The tie-bar wires 2x and 2y have a U-shaped planar pattern to surround the side surface of the sealing resin 10. FIG. 2 illustrates a final state of the semiconductor device according to the first embodiment, in which the tie-bar wires 2x and 2y are cut out so that the positive electrode terminal 2b and the output terminal 2c are separated from each other.

As illustrated in FIG. 1 and FIG. 2, the sealing resin 10 has a substantially cuboidal shape. The sealing resin 10 is made of resin material such as epoxy resin that has insulating properties.

The positive electrode terminal 2b and the negative electrode terminal 2a each partly project from the same side surface of the sealing resin 10. The positive electrode terminal 2b and the negative electrode terminal 2a include conductive material such as copper (Cu), a Cu alloy, aluminum (Al), and an Al alloy.

The negative electrode terminal 2a is provided on the top surface side of the positive electrode terminal 2b with an insulating member 91 interposed. The negative electrode terminal 2a and the positive electrode terminal 2b are arranged adjacent to each other (laminated together). The phrase “arranged adjacent to each other” as used herein refers to a state in which the negative electrode terminal 2a and the positive electrode terminal 2b at least partly overlap with each other with an insulating member such as the insulating member 91 interposed. The insulating member 91 is provided with a covering part 94 covering a part of the positive electrode terminal 2b, and a frame part 95 provided on the top surface side of the covering part 94 to surround the circumference of the negative electrode terminal 2a. A part of the insulating member 91 is covered with the sealing resin 10. The insulating member 91 includes insulating material such as resin, rubber, or ceramic, for example.

The output terminal 2c partly projects from the side surface of the sealing resin 10 on the opposite side of the side surface from which the negative electrode terminal 2a and the positive electrode terminal 2b partly project. The output terminal 2c includes conductive material such as copper (Cu), a Cu alloy, aluminum (Al), and an Al alloy. The output terminal 2c, the positive electrode terminal 2b, and the tie-bar wires 2x and 2y may include the same material.

A part of the output terminal 2c is covered with an insulating member 93. A part of the insulating member 93 is covered with the sealing resin 10. The insulating member 93 includes insulating material such as resin, rubber, or ceramic, for example.

The control terminals 4a to 4g each partly project from the top surface of the sealing resin 10. The respective control terminals 4a to 4g include conductive material such as copper (Cu), a Cu alloy, aluminum (Al), and an Al alloy. While FIG. 1 and FIG. 2 illustrate the case in which the control terminals 4a to 4g are each a press-fit pin, the control terminals 4a to 4g may have any shape determined as appropriate. The lower parts of the control terminals 4a to 4d are fixed by the insulating member 41. The lower parts of the control terminals 4e to 4g are covered with the insulating member 42. The respective insulating members 41 and 42 include insulating material such as resin, rubber, or ceramic, for example.

In FIG. 1 and FIG. 2, a direction parallel to the top surface of the sealing resin 10 in which the negative electrode terminal 2a, the positive electrode terminal 2b, and the output terminal 2c project from the sealing resin 10 is defined as an X-axis direction, and the rightward direction in the planar view of FIG. 2 is defined as a positive direction of the X-axis direction. In FIG. 1 and FIG. 2, a direction parallel to the top surface of the sealing resin 10 and perpendicular to the X-axis direction is defined as a Y-axis direction, and the upper direction in the planar view of FIG. 2 is defined as a positive direction of the Y-axis direction. In FIG. 1 and FIG. 2, a direction perpendicular to the X-axis direction and the Y-axis direction is defined as a Z-axis direction, and the frontward direction in the planar view of FIG. 2 is defined as a positive direction of the Z-axis direction. The same definitions are also applied to the following explanations regarding the drawings other than the FIG. 1 and FIG. 2.

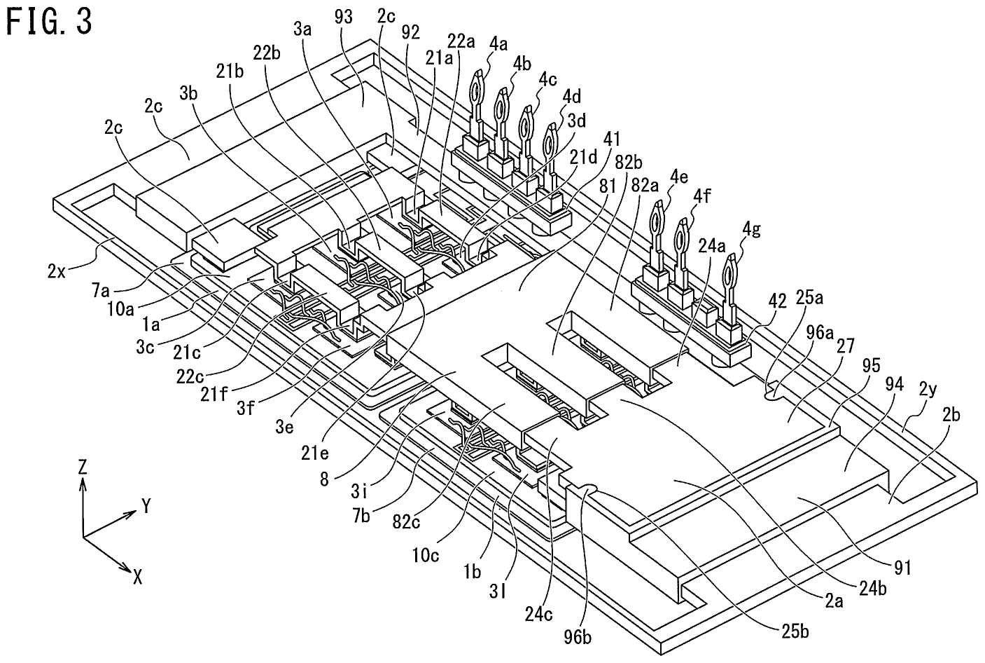

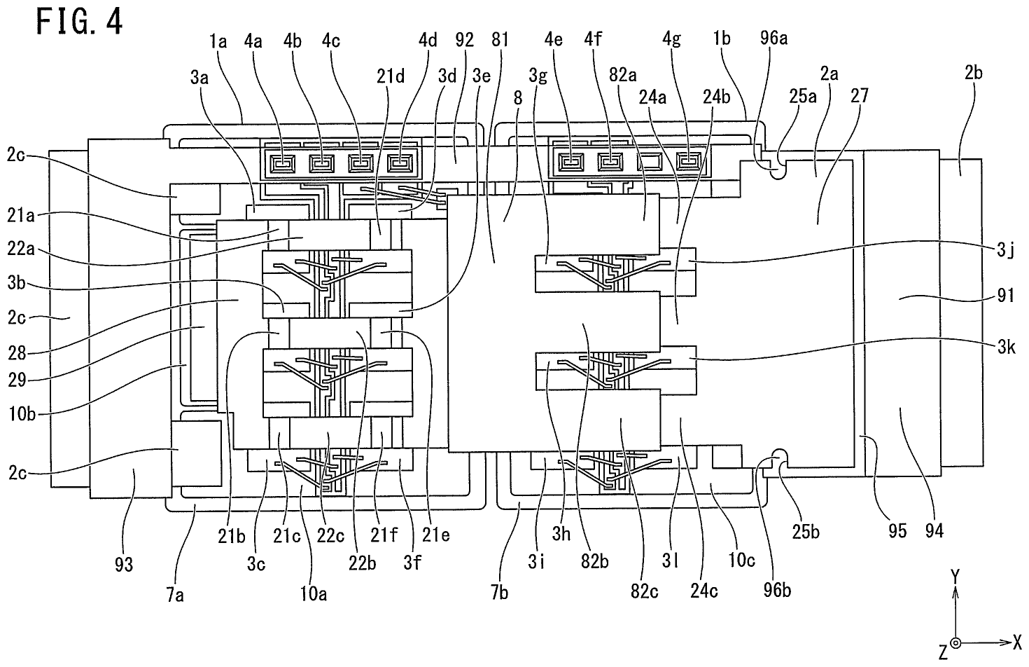

FIG. 3 is a perspective view illustrating the semiconductor device according to the first embodiment illustrated in FIG. 1 while omitting the illustration of the sealing resin 10, and FIG. 4 is a plan view illustrating the semiconductor device according to the first embodiment illustrated in FIG. 2 while omitting the illustration of the sealing resin 10.

As illustrated in FIG. 3 and FIG. 4, the semiconductor device according to the first embodiment includes insulated circuit substrates 1a and 1b, and semiconductor chips 3a to 3l provided on the top surface side of the respective insulated circuit substrates 1a and 1b. An integrated structure body (2a, 6, 8) in which the negative electrode terminal 2a, a conductive member 6 (also referred to as an “intermediate clip” or “lead frame”), and an insulating member 8 are integrated together is provided on the top surface side of the insulated circuit substrates 1a and 1b and the semiconductor chips 3a to 3l. An integrated structure body (2b, 2c, 91 to 93) in which the positive electrode terminal 2b, the output terminal 2c, and the insulating members 91 to 93 are integrated together is provided on the top surface side of the insulated circuit substrates 1a and 1b so as to surround the circumference of the respective semiconductor chips 3a to 3l and the integrated structure body (2a, 6, 8) in the planar view.

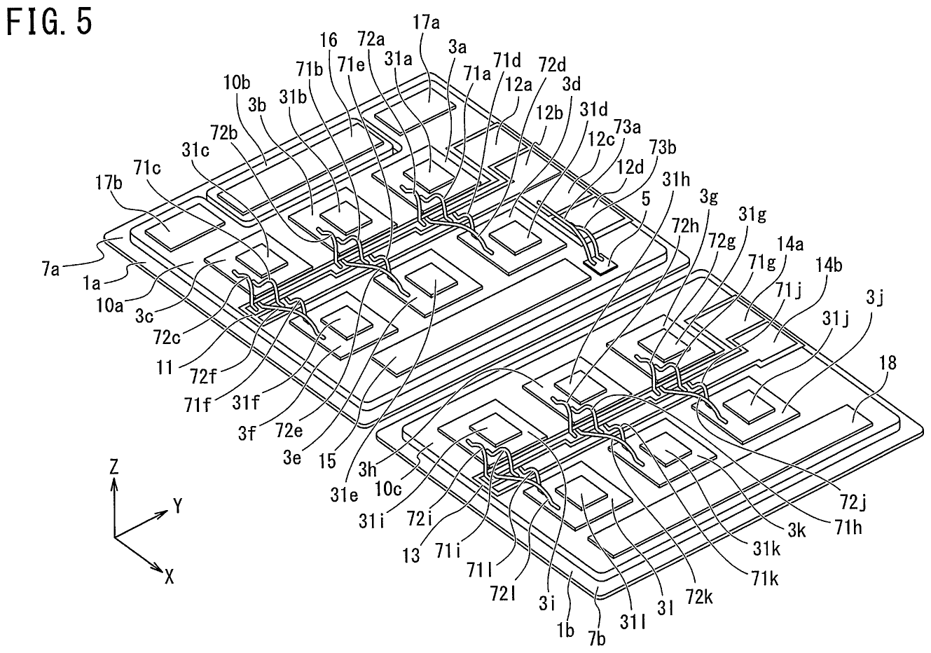

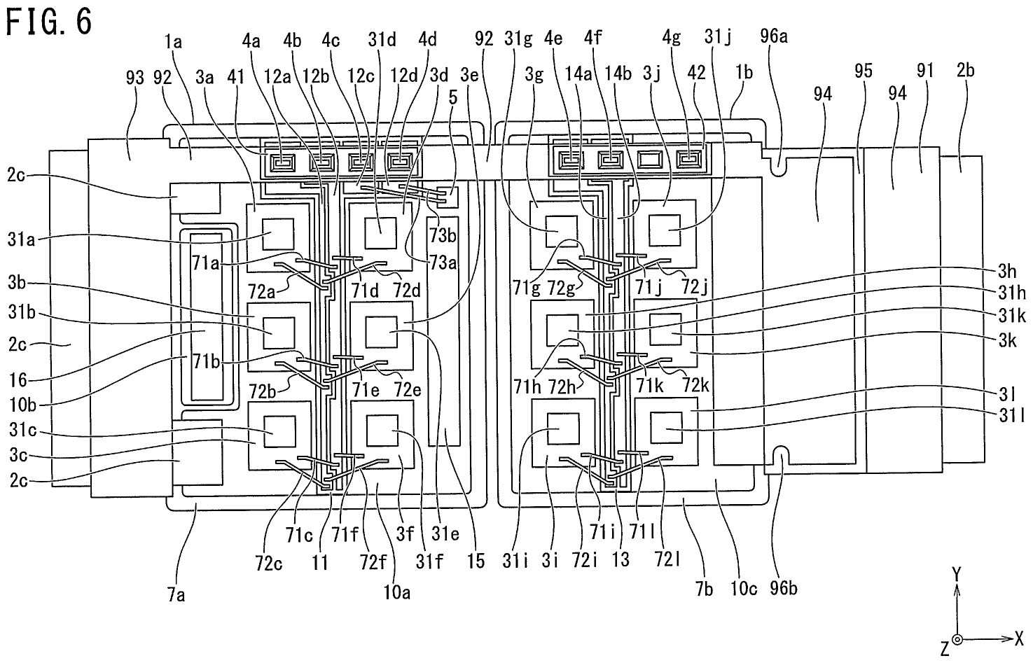

FIG. 5 is a perspective view illustrating the insulated circuit substrates 1a and 1b and the semiconductor chips 3a to 3l that are the constitutional elements of the semiconductor device according to the first embodiment, and FIG. 6 is a plan view illustrating the insulated circuit substrates 1a and 1b, the semiconductor chips 3a to 3l, and the integrated structure body (2b, 2c, 91 to 93) that are the constitutional elements of the semiconductor device according to the first embodiment.

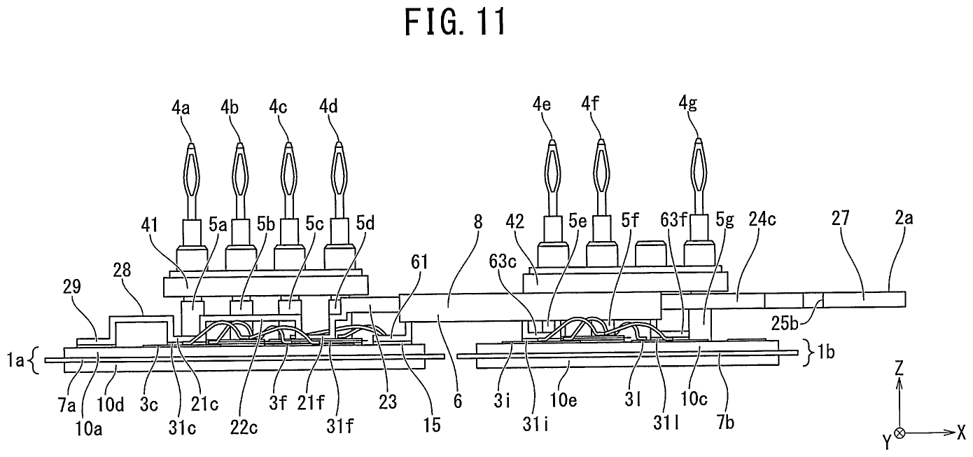

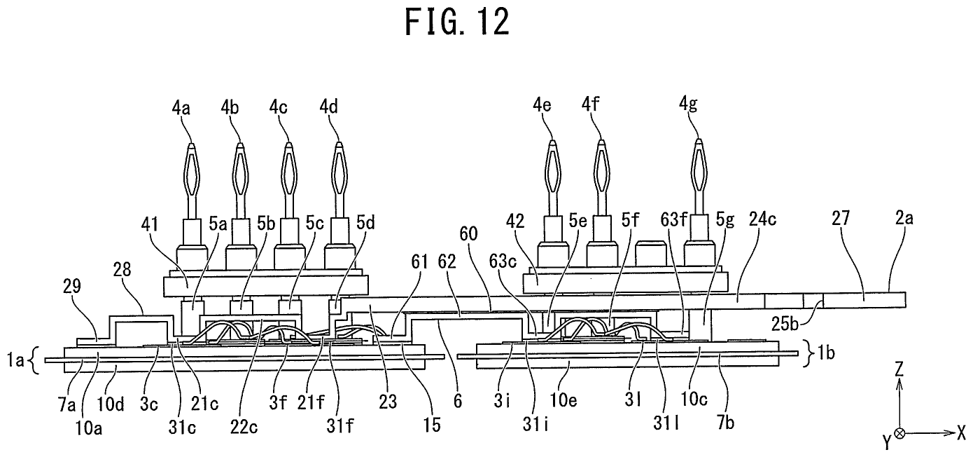

As illustrated in FIG. 5 and FIG. 6, the insulated circuit substrates 1a and 1b are provided separately from each other. The insulated circuit substrate 1a includes an insulating plate 7a, conductive plates 10a and 10b provided on the top surface side of the insulating plate 7a, and a conductive plate 10d (refer to FIG. 11 and FIG. 12) provided on the bottom surface side of the insulating plate 7a. The insulated circuit substrate 1b includes an insulating plate 7b, a conductive plate 10c provided on the top surface side of the insulating plate 7b, and a conductive plate 10e (refer to FIG. 11 and FIG. 12) provided on the bottom surface side of the insulating plate 7b. The insulated circuit substrates 1a and 1b may each be a direct copper bonded (DCB) substrate or an active metal brazed (AMB) substrate, for example.

The insulating plates 7a and 7b as used herein are each a resin insulating layer including polymer material or a ceramic plate mainly including aluminum oxide (Al₂O₃), aluminum nitride (AlN), silicon nitride (Si₃N₄), or boron nitride (BN), for example. The respective insulating plates 7a and 7b have a substantially rectangular planar pattern.

The respective conductive plates 10a to 10e include conductive material such as copper (Cu), a Cu alloy, aluminum (Al), and an Al alloy. The conductive plate 10a has a substantially rectangular planar pattern, and is provided with a recess toward the output terminal 2c in the planar pattern. The conductive plate 10b is located in the recess of the conductive plate 10a in the planar pattern, and has a substantially rectangular planar pattern. The conductive plate 10c has a substantially rectangular planar pattern. The conductive plates 10d and 10e (refer to FIG. 11 and FIG. 12) each have a substantially rectangular planar pattern. The respective bottom surfaces of the conductive plates 10d and 10e are exposed to the outside of the sealing resin 10 illustrated in FIG. 1 and FIG. 2.

As illustrated in FIG. 5 and FIG. 6, the plural (six) power semiconductor elements (semiconductor chips) 3a to 3f are bonded onto the top surface side of the conductive plate 10a via bonding material such as solder, a conductive adhesive, or sintered material. The semiconductor chips 3a to 3f are electrically connected in parallel to the conductive plate 10a such that the semiconductor chips 3a to 3c are arranged in a first row, and the semiconductor chips 3d to 3f are arranged in a second row.

The solder used as the bonding material for bonding the respective members to each other in the semiconductor device according to the first embodiment can be lead-free solder such as thin-antimony-based (Sn—Sb), thin-copper-based (Sn—Cu), thin-copper-silver-based (Sn—Cu—Ag), tin-silver-based (Sn—Ag), thin-silver-copper-based (Sn—Ag—Cu), thin-silver-bismuth-copper-based (Sn—Ag—Bi—Cu), tin-indium-silver-bismuth-based (Sn—In—Ag—Bi), tin-zinc-based (Sn—Zn), tin-zinc-bismuth-based (Sn—Zn—Bi), tin-bismuth-based (Sn—Bi), or tin-indium-based (Sn—In) solder, or leaded solder such as tin-lead-based (Sn—Pb) solder, for example. The conductive adhesive used as the bonding material for bonding the respective members to each other in the semiconductor device according to the first embodiment can be an adhesive in which resin such as epoxy resin is mixed with metallic particles such as silver (Ag), for example. The sintered material used as the bonding material for bonding the respective members to each other in the semiconductor device according to the first embodiment can be obtained such that a sintered sheet or conductive paste, including metallic particles or an organic component (binder) such as gold (Au), silver (Ag), or copper (Cu) having a fine particle diameter of about several nanometers to several micrometers, is applied with pressure while being heated so as to be sintered.

The plural (six) power semiconductor elements (semiconductor chips) 3g to 3l are bonded onto the top surface side of the conductive plate 10c via bonding material such as solder, a conductive adhesive, or sintered material. The semiconductor chips 3g to 3l are electrically connected in parallel to the conductive plate 10c such that the semiconductor chips 3g to 3i are arranged in a first row, and the semiconductor chips 3j to 3l are arranged in a second row.

The semiconductor device according to the first embodiment is illustrated with the case in which the semiconductor chips 3a to 3l are each a MOSFET, and is illustrated with a 2-in-1 power semiconductor module including two sets arranged in series each including six MOSFETs, in which the six MOSFETs in each set are arranged in parallel. The respective semiconductor chips 3a to 3f implement a lower arm and the respective semiconductor chips 3g to 3l implement an upper arm of a half bridge for one phase of a three-phase inverter circuit.

The respective semiconductor chips 3a to 3l include a semiconductor substrate, a first main electrode (a drain electrode) provided on the bottom surface side of the semiconductor substrate, second main electrodes (source electrodes) 31a to 31l provided on the top surface side of the respective semiconductor substrates, a control electrode (a gate electrode), and an auxiliary source electrode. The respective drain electrodes of the semiconductor chips 3a to 3f are electrically connected to the conductive plate 10a. The respective drain electrodes of the semiconductor chips 3g to 3l are electrically connected to the conductive plate 10c.

The semiconductor substrate of the respective semiconductor chips 3a to 3l includes silicon (Si), silicon carbide (SiC), gallium nitride (GaN), gallium oxide (Ga₂O₃), or diamond (C), for example. The arranged positions and the number of the semiconductor chips 3a to 3l may be determined as appropriate. The semiconductor chips 3a to 3l may each be a field-effect transistor (FET) such as a MOSFET, or may each be an insulated gate bipolar transistor (IGBT), a reverse conductive IGBT (RC-IGBT) in which a diode is connected in antiparallel to an IGBT, a static induction (SI) thyristor, or a gate turn-off (GTO) thyristor.

As illustrated in FIG. 5 and FIG. 6, a pad 15 is provided on the top surface side of the conductive plate 10a on the side toward the conductive plate 10c. The top surface side of the conductive plate 10a is also provided with pads 17a and 17b on the side toward the output terminal 2c. A pad 16 is provided on the top surface side of the conductive plate 10b. A pad 18 is provided on the top surface side of the conductive plate 10c on the side toward the positive electrode terminal 2b.

The pads 15, 16, 17a, 17b, and 18 are bonded to the respective top surfaces of the conductive plates 10a to 10c via bonding material such as solder, a conductive adhesive, and sintered material. The respective pads 15, 16, 17a, 17b, and 18 include conductive material such as copper (Cu), a Cu alloy, aluminum (Al), and an Al alloy. The pads 15, 16, 17a, 17b, and 18 may each be a projection formed integrally with the conductive plates 10a to 10c.

As illustrated in FIG. 5 and FIG. 6, a temperature detection chip 5 is provided on the top surface side of the conductive plate 10a on the side toward the conductive plate 10c. The temperature detection chip 5 is bonded to the top surface side of the conductive plate 10a via bonding material such as solder, a conductive adhesive, and sintered material.

As illustrated in FIG. 5 and FIG. 6, the top surface side of the conductive plate 10a is provided with a printed board (11, 12a to 12d) for control wiring, which is referred to also as a “control wiring board”. The printed board (11, 12a to 12d) includes an insulating layer 11, conductive layers 12a to 12d provided separately from each other on the top surface side of the insulating layer 11, and a conductive layer (not illustrated) provided on the bottom surface side of the insulating layer 11. The conductive layer provided on the bottom surface side of the insulating layer 11 is bonded to the conductive plate 10a via bonding material such as solder, a conductive adhesive, and sintered material.

The insulating layer 11 is a ceramic plate mainly including aluminum oxide (Al₂O₃), aluminum nitride (AlN), silicon nitride (Si₃N₄), or boron nitride (BN), or a resin insulating layer including polymer material. The resin insulating layer may be obtained such that glass fiber is impregnated with epoxy resin. The insulating layer 11 includes a first region extending in one direction (in the upper-lower direction in FIG. 6) between the respective semiconductor chips 3a to 3c and the respective semiconductor chips 3d to 3f, and a second region extending in a direction perpendicular to the first region (in the right-left direction in FIG. 6). While FIG. 5 and FIG. 6 illustrate the case in which the insulating layer 11 has a T-shaped planar pattern, the insulating layer 11 is not limited to this pattern, and may have an L-shaped planar pattern instead.

The respective conductive layers 12a to 12d include conductive material such as copper (Cu), a Cu alloy, aluminum (Al), and an Al alloy. The conductive layers 12a to 12d are arranged in line in the second region of the insulating layer 11. The conductive layers 12a and 12b are arranged across the first region and the second region of the insulating layer 11.

The respective conductive layers 12a and 12b extend from the end part of the conductive plate 10a between the respective semiconductor chips 3a to 3c and the respective semiconductor chips 3d to 3f. The conductive layers 12a and 12b each have a wide region arranged next to each other.

The respective gate electrodes of the semiconductor chips 3a to 3f are electrically connected to the wide region of the conductive layer 12a via control wires (bonding wires) 72a to 72f. The control terminal 4a is bonded to the conductive layer 12a via bonding material such as solder, a conductive adhesive, and sintered material. The control terminal 4a extends in the upward direction vertical to the top surface of the conductive layer 12b. The control terminal 4a applies control signals to the respective gate electrodes of the semiconductor chips 3a to 3f via the conductive layer 12a and the respective bonding wires 72a to 72f.

The respective source electrodes (not illustrated) of the semiconductor chips 3a to 3f are partly and electrically connected to the wide region of the conductive layer 12b via control wires (bonding wires) 71a to 71f. The control terminal 4b is bonded to the conductive layer 12b via bonding material such as solder, a conductive adhesive, and sintered material. The control terminal 4b extends in the upward direction vertical to the top surface of the conductive layer 12b. The control terminal 4b is connected to the respective source electrodes of the semiconductor chips 3a to 3f so as to conduct electricity through the bonding wires 71a to 71f and the conductive layer 12b. A voltage is applied to the control terminal 4b when the respective semiconductor chips 3a to 3f are turned ON, and the voltage of the control terminal 4b to which a threshold voltage or greater of the respective semiconductor chips 3a to 3f is added is applied to the control terminal 4a.

One of the electrodes of the temperature detection chip 5 is connected to the conductive layer 12c via the control wire (the bonding wire) 73a. The temperature detection chip 5 as used herein is a diode for temperature detection, for example. The control terminal 4c is bonded to the conductive layer 12c via bonding material such as solder, a conductive adhesive, and sintered material. The control terminal 4c extends in the upward direction vertical to the top surface of the conductive layer 12c. The control terminal 4c is connected to the ground so as to transmit a ground voltage to the temperature detection chip 5 through the conductive layer 12c and the bonding wire 73a.

The other one of the electrodes of the temperature detection chip 5 is connected to the conductive layer 12d via the control wire (the bonding wire) 73b. The control terminal 4d is bonded to the conductive layer 12d via bonding material such as solder, a conductive adhesive, and sintered material. The control terminal 4d extends in the upward direction vertical to the top surface of the conductive layer 12d. The control terminal 4d is connected to the temperature detection chip 5 via the conductive layer 12d and the bonding wire 73b so as to measure a forward voltage of the diode for temperature detection to detect the temperature, for example.

A printed board (13, 14a, 14b) for control wiring is arranged on the top surface side of the conductive plate 10c. The printed board (13, 14a, 14b) includes an insulating layer 13, and conductive layers 14a and 14b provided separately from each other on the top surface side of the insulating layer 13. The insulating layer 13 can include material similar to that included in the insulating layer 11, and the respective conductive layers 14a and 14b can include material similar to that included in the respective conductive layers 12a to 12d.

The insulating layer 13 includes a first region extending in one direction (in the upper-lower direction in FIG. 6) between the respective semiconductor chips 3g to 3i and the respective semiconductor chips 3j to 3l, and a second region extending in a direction perpendicular to the first region (in the right-left direction in FIG. 6). While FIG. 5 and FIG. 6 illustrate the case in which the insulating layer 13 has a T-shaped planar pattern, the insulating layer 13 is not limited to this pattern, and may have an L-shaped planar pattern instead.

The respective conductive layers 14a and 14b are arranged across the first region and the second region of the insulating layer 13. The respective conductive layers 14a and 14b extend from the end part of the conductive plate 10c between the respective semiconductor chips 3g to 3i and the respective semiconductor chips 3j to 3l. The conductive layers 14a and 14b each have a wide region arranged next to each other.

The respective gate electrodes of the semiconductor chips 3g to 3l are electrically connected to the wide region of the conductive layer 14a via control wires (bonding wires) 72g to 72l. The control terminal 4e is bonded to the conductive layer 14a via bonding material such as solder, a conductive adhesive, and sintered material. The control terminal 4e extends in the upward direction vertical to the top surface of the conductive layer 14a. The control terminal 4e applies control signals to the respective gate electrodes of the semiconductor chips 3g to 3l via the conductive layer 14a and the bonding wires 72g to 72l.

The respective source electrodes (not illustrated) of the semiconductor chips 3g to 3l are partly and electrically connected to the wide region of the conductive layer 14b via control wires (bonding wires) 71g to 71l. The control terminal 4f is bonded to the conductive layer 14b via bonding material such as solder, a conductive adhesive, and sintered material. The control terminal 4f extends in the upward direction vertical to the top surface of the conductive layer 14b. The control terminal 4f is connected to the source electrodes of the semiconductor chips 3g to 3l so as to conduct electricity through the bonding wires 71g to 71l and the conductive layer 14b. A voltage is applied to the control terminal 4f when the respective semiconductor chips 3g to 3l are turned ON, and the voltage of the control terminal 4f to which a threshold voltage or greater of the respective semiconductor chips 3g to 3l is added is applied to the control terminal 4e.

The control terminal 4g is bonded to the top surface side of the conductive plate 10c via bonding material such as solder, a conductive adhesive, and sintered material. The control terminal 4g extends in the upward direction vertical to the top surface of the conductive layer 10c.

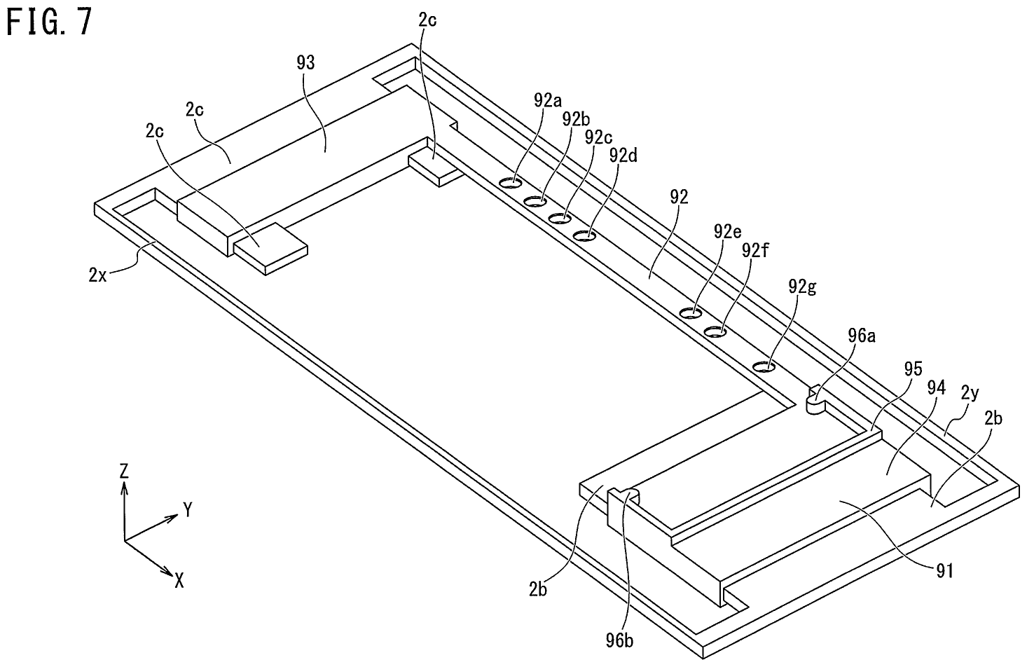

FIG. 7 is a perspective view illustrating the integrated structure body (2b, 2c, 91 to 93) that is the constitutional element of the semiconductor device according to the first embodiment. FIG. 7 illustrates the integrated structure body (2b, 2c, 91 to 93) in a state during assembly, in which the positive electrode terminal 2b and the output terminal 2c are provided integrally with the tie-bar wires 2x and 2y.

As illustrated in FIG. 6 and FIG. 7, the integrated structure body (2b, 2c, 91 to 93) includes the positive electrode terminal 2b, the output terminal 2c, and the insulating members 91 to 93. The positive electrode terminal 2b and the output terminal 2c are partly covered with the insulating members 91 and 93 so that the positive electrode terminal 2b, the output terminal 2c, and the insulating members 91 to 93 are in the integrated state.

The positive electrode terminal 2b has a flat plate-like shape with a substantially rectangular planar pattern. As illustrated in FIG. 5 and FIG. 6, the positive electrode terminal 2b is bonded to the pad 18 on the top surface side of the conductive plate 10c via bonding material such as solder, a conductive adhesive, and sintered material, or by direct bonding.

The output terminal 2c has a flat plate-like shape with a U-shaped planar pattern. As illustrated in FIG. 5 and FIG. 6, the output terminal 2c is bonded to the respective pads 17a and 17b on the top surface side of the conductive plate 10a via bonding material such as solder, a conductive adhesive, and sintered material, or by direct bonding.

FIG. 6 and FIG. 7 illustrate the case in which the insulating members 91 to 93 are formed integrally with each other. The insulating member 92 is provided continuously next to the insulating member 91, and the insulating member 93 is provided continuously next to the insulating member 92. The semiconductor device according to the first embodiment does not necessarily include the insulating members 92 and 93 but only needs to include the insulating member 91. Alternatively, the semiconductor device according to the first embodiment may include the insulating members 91 and 92 without including the insulating member 93, or may include the insulating members 91 and 93 without including the insulating member 92. The respective insulating members 91 to 93 may be provided separately from each other without being integrated with each other.

As illustrated in FIG. 6 and FIG. 7, the insulating member 91 includes a covering part 94 and further includes a frame part 95 and engagement parts 96a and 96b provided on the top surface side of the covering part 94. The covering part 94 covers a part of the positive electrode terminal 2b along the entire periphery (the upper and lower surfaces and the both side surfaces). As illustrated in FIG. 3 and FIG. 4, the negative electrode terminal 2a is arranged on the top surface side of the covering part 94. The covering part 94 has a function of keeping an insulating distance between the positive electrode terminal 2b and the negative electrode terminal 2a and keeping an insulating distance between the positive electrode terminal 2b and ground.

As illustrated in FIG. 6 and FIG. 7, the frame part 95 has a substantially U-shaped planar pattern. As illustrated in FIG. 3 and FIG. 4, the respective side surfaces of the negative electrode terminal 2a when located on the top surface side of the covering part 94 are surrounded by the frame part 95. The frame part 95 has a function of positioning the negative electrode terminal 2a and keeping an insulating distance between the negative electrode terminal 2a and the positive electrode terminal 2b.

As illustrated in FIG. 6 and FIG. 7, the engagement parts 96a and 96b are provided at the respective ends on both sides of the frame part 95. The engagement parts 96a and 96b are projecting parts projecting to face each other, for example. As illustrated in FIG. 3 and FIG. 4, the negative electrode terminal 2a is provided with engagement parts 25a and 25b that are recessed parts on the side surfaces of the negative electrode terminal 2a. The engagement parts 96a and 96b of the insulating member 91 engage with the engagement parts 25a and 25b of the negative electrode terminal 2a when arranged on the top surface side of the covering part 94 so that the negative electrode terminal 2a is positioned and fixed. The engagement parts 96a and 96b of the insulating member 91 and the engagement parts 25a and 25b of the negative electrode terminal 2a are sealed with the sealing resin 10 illustrated in FIG. 1 and FIG. 2.

The arranged position, the number, and the shape of each of the engagement parts 96a and 96b of the insulating member 91 and the engagement parts 25a and 25b of the negative electrode terminal 2a can be determined as appropriate. For example, the engagement parts of the insulating member 91 may be formed into recessed parts, and the engagement parts of the negative electrode terminal 2a may be formed into projecting parts. Alternatively, the engagement parts of the insulating member 91 may be formed into projecting parts in the middle of the top surface side of the covering part 94 of the insulating member 91, and the engagement parts of the negative electrode terminal 2a may be formed into recessed parts on the bottom surface side of the negative electrode terminal 2a or penetration holes penetrating the top and bottom surfaces. Alternatively, only one of the engagement parts 96a and 96b of the insulating member 91 and the corresponding one of the engagement parts 95a and 95b of the negative electrode terminal 2a may be provided. Namely, the arranged position, the number, and the shape only need to be determined such that the engagement parts of the insulating member 91 engage with the engagement parts of the negative electrode terminal 2a so as to position the negative electrode terminal 2a reliably.

As illustrated in FIG. 6 and FIG. 7, the insulating member 92 has a substantially straight (stripe-shaped or beam-shaped) planar pattern. The insulating member 92 has a smaller thickness than the covering part 94 of the insulating member 91. The top surface of the insulating member 92 is located at substantially the same height as the top surface of each of the covering part 94 of the insulating member 91 and the insulating member 93. The insulating member 92 is provided with openings 92a to 92g penetrating the insulating member 92 in the thickness direction. The openings 92a to 92g have a function of positioning the corresponding control terminals 4a to 4g. As illustrated in FIG. 3, FIG. 4, and FIG. 6, the control terminals 4a to 4g are inserted to the corresponding openings 92a to 92g so as to be positioned and fixed.

As illustrated in FIG. 6 and FIG. 7, the insulating member 93 covers a part of the output terminal 2c along the entire periphery. Both ends of the output terminal 2c having the U-shaped planar pattern project from the side surface of the insulating member 93 on the positive electrode terminal 2b side. The insulating member 93 has substantially the same thickness as the covering part 94 of the insulating member 91, and has a greater thickness than the insulating member 92. The insulating member 93 keeps an insulating distance between the output terminal 2c and ground. The insulating member 93 is formed integrally with the respective insulating members 91 and 92, so as to prevent bending of the insulating member 92.

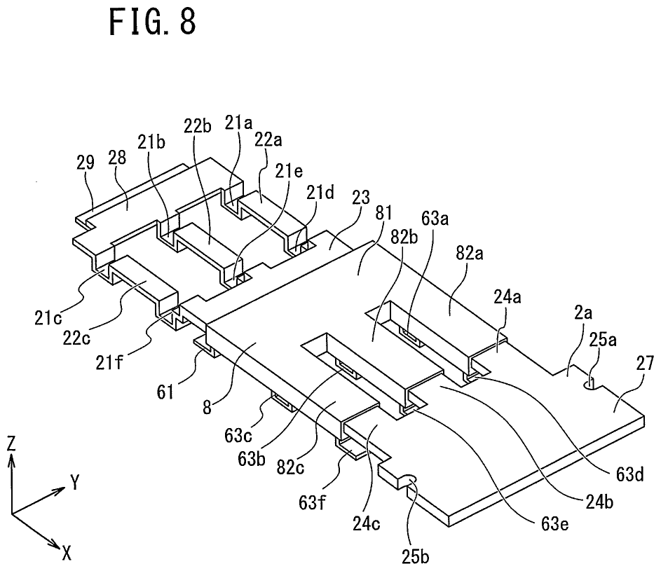

FIG. 8 is a perspective view illustrating the integrated structure body (2a, 6, 8) that is the constitutional element of the semiconductor device according to the first embodiment. As illustrated in FIG. 8, the integrated structure body (2a, 6, 8) includes the negative electrode terminal 2a, the conductive member 6, and the insulating member 8. The negative electrode terminal 2a is provided on the top surface side of the conductive member 6. The negative electrode terminal 2a and the conductive member 6 are partly covered with the insulating member 8 so that the negative electrode terminal 2a, the conductive member 6, and the insulating member 8 are in the integrated state.

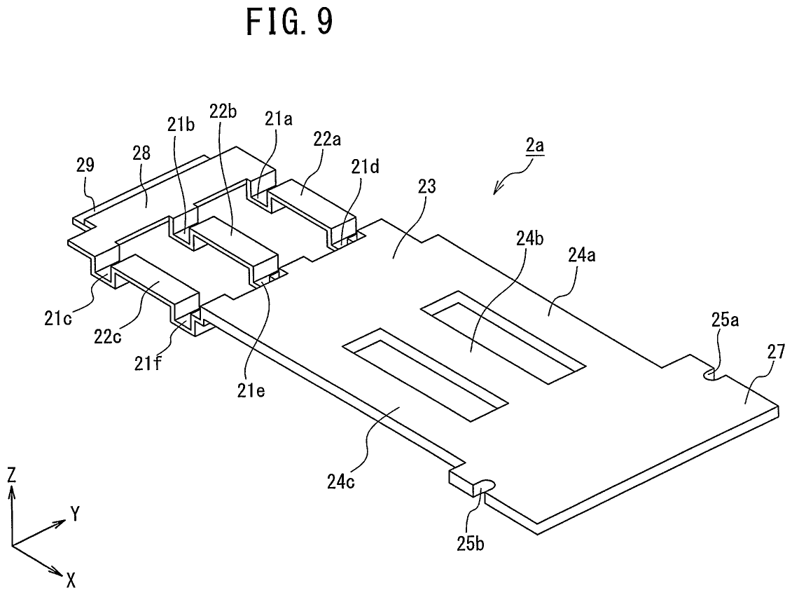

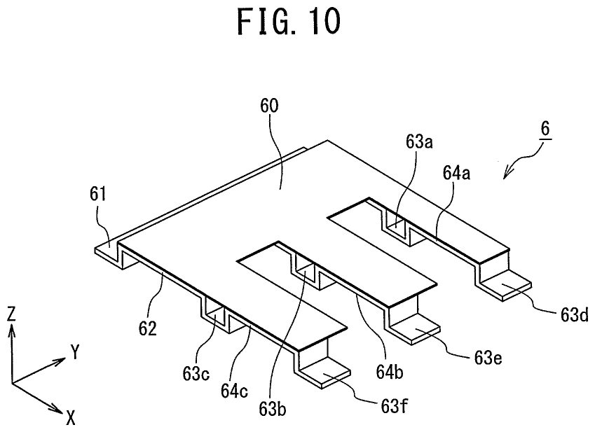

FIG. 9 is a perspective view illustrating the negative electrode terminal 2a that is the constitutional element of the integrated structure body (2a, 6, 8) illustrated in FIG. 8. FIG. 10 is a perspective view illustrating the conductive member 6 that is the constitutional element of the integrated structure body (2a, 6, 8) illustrated in FIG. 8. FIG. 11 is a side view illustrating the semiconductor device according to the first embodiment while omitting the illustration of the integrated structure body (2b, 2c, 91 to 93). FIG. 12 is a side view illustrating the semiconductor device according to the first embodiment while omitting the illustration of the integrated structure body (2b, 2c, 91 to 93) and further omitting the insulating member 8 that is the constitutional element of the integrated structure body (2a, 6, 8).

As illustrated in FIG. 8 to FIG. 12, the negative electrode terminal 2a includes a pad bonding part 29, a connection part 28 connected to the pad bonding part 29, chip bonding parts 21a to 21c connected to the connection part 28, connection parts 22a to 22c connected to the chip bonding parts 21a to 21c, chip bonding parts 21d to 21f connected to the connection parts 22a to 22c, a connection part 23 connected to the chip bonding parts 21d to 21f, connection parts 24a to 24c connected to the connection part 23, and a terminal part 27 connected to the connection parts 24a to 24c.

The pad bonding part 29 is a bent part projecting downward from the connection part 28. The pad bonding part 29 is bonded to the pad 16 on the top surface side of the conductive plate 10b illustrated in FIG. 5 and FIG. 6 via bonding material such as solder, a conductive adhesive, and sintered material.

The connection part 28 has a substantially rectangular planar pattern. The chip bonding parts 21a to 21f are bent parts projecting downward from the connection part 28 and the connection parts 22a to 22c. The chip bonding parts 21a to 21f are bonded to the source electrodes 31a to 31f of the semiconductor chips 3a to 3f illustrated in FIG. 5 and FIG. 6 via bonding material such as solder, a conductive adhesive, and sintered material.

The connection parts 22a to 22c are separated from each other and have a stripe-shaped planar pattern extending parallel to each other. The connection part 23 has an outer shape with a substantially rectangular planar pattern. The connection parts 24a to 24c are separated from each other and have a stripe-shaped planar pattern extending parallel to each other. The connection part 23 and the connection parts 24a to 24c are partly covered with the insulating member 8 illustrated in FIG. 8.

The terminal part 27 has a substantially rectangular planar pattern. The engagement parts 25a and 25b are provided on the side surfaces of the terminal part 27. The terminal part 27 is arranged on the top surface side of the positive electrode terminal 2b with the insulating member 91 interposed, as illustrated in FIG. 3 and FIG. 4. The terminal part 27 projects from the side surface of the sealing resin 10, as illustrated in FIG. 1 and FIG. 2.

Instead of the negative electrode terminal 2a itself, the terminal part 27 that is a part of the negative electrode terminal 2a may be referred to as a “negative electrode terminal”, and the pad bonding part 29, the connection part 28, the chip bonding parts 21a to 21c, the connection parts 22a to 22c, the chip bonding parts 21d to 21f, the connection part 23, and the connection parts 24a to 24c, other than the terminal part 27, may be referred to as a “lead frame” or “clip” integrated with the “negative electrode terminal”.

As illustrated in FIG. 10 to FIG. 12, the conductive member 6 includes a pad bonding part 61, a connection part 62 connected to the pad bonding part 61, chip bonding parts 63a to 63c connected to the connection part 62, connection parts 64a to 64c connected to the chip bonding parts 63a to 63c, and chip bonding parts 63d to 63f connected to the connection parts 64a to 64c.

The pad bonding part 61 is a bent part projecting downward from the connection part 62. The pad bonding part 61 is exposed on the bottom surface of the insulating member 8 illustrated in FIG. 8. The pad bonding part 61 is bonded to the pad 15 on the top surface side of the conductive plate 10a illustrated in FIG. 5 and FIG. 6 via bonding material such as solder, a conductive adhesive, and sintered material.

The connection part 62 has a substantially rectangular planar pattern. The connection part 62 is covered with the insulating member 8 illustrated in FIG. 8.

The chip bonding parts 63a to 63f are bent parts projecting downward from the connection part 62 and the respective connection parts 64a to 64c. The chip bonding parts 63a to 63f are exposed on the bottom surface of the insulating member 8 illustrated in FIG. 8. The chip bonding parts 63a to 63f are bonded to the source electrodes 31g to 31l of the semiconductor chips 3g to 3l illustrated in FIG. 5 and FIG. 6 via bonding material such as solder, a conductive adhesive, and sintered material.

The connection parts 64a to 64c are separated from each other and have a stripe-shaped planar pattern extending parallel to each other. The connection parts 64a to 64c are covered with the insulating member 8 illustrated in FIG. 8.

As illustrated in FIG. 10, a plate-like (sheet-like) insulating member (insulating sheet) 60 is arranged to cover the top surface side of the connection part 62 and the respective connection parts 64a to 64c of the conductive member 6. The insulating member 60 is interposed between the conductive member 6 and the negative electrode terminal 2a so as to be covered with the insulating member 8. The insulating member 60 as used herein can be an insulating paper or can include insulating material having high insulating and heat-resistant properties such as polyimide or polyamide.

As illustrated in FIG. 8, the insulating member 8 includes a covering part 81 having a substantially rectangular parallelepiped external shape, and covering parts 82a to 82c connected to the covering part 81. The covering part 81 covers the connection part 23 of the negative electrode terminal 2a illustrated in FIG. 9 and the connection part 62 of the conductive member 6 illustrated in FIG. 10 with the insulating member 60 interposed. The covering parts 82a to 82c cover the respective connection parts 24a to 24c of the negative electrode terminal 2a illustrated in FIG. 9 and the respective connection parts 64a to 64c of the conductive member 6 illustrated in FIG. 10 with the insulating member 60 interposed.

As illustrated in FIG. 11 and FIG. 12, support parts (sleeves) 5a to 5g are bonded to the top surface sides of the respective conductive layers 12a to 12d, 14a, and 14b, and the conductive plate 10c illustrated in FIG. 5 via bonding material such as solder, a conductive adhesive, and sintered material. The sleeves 5a to 5g include conductive material such as copper (Cu), a Cu alloy, aluminum (Al), and an Al alloy. The lower parts of the control terminals 4a to 4g projecting from the respective bottom surfaces of the insulating members 41 and 42 are press-fitted and fixed to the corresponding sleeves 5a to 5g.

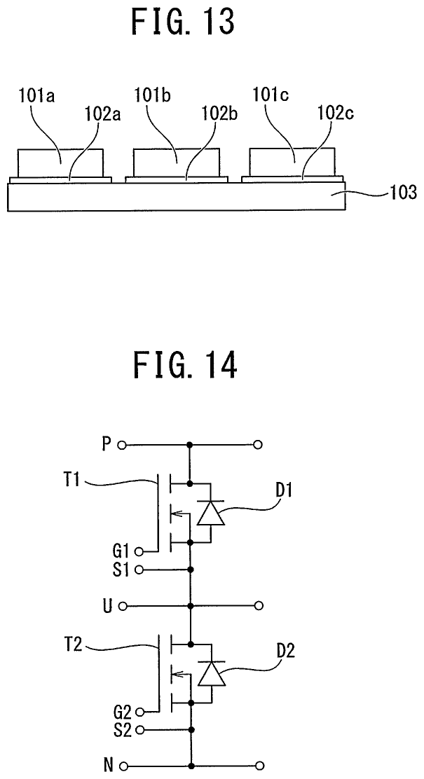

FIG. 13 is a schematic side view illustrating a packaged structure of semiconductor devices 101a to 101c according to the first embodiment. The semiconductor devices 101a to 101c each correspond to the semiconductor device according to the first embodiment illustrated in FIG. 1 and FIG. 2. The bottom surfaces of the conductive plates 10d and 10e illustrated in FIG. 11 and FIG. 12 are exposed to the respective bottom surfaces of the semiconductor devices 101a to 101c. A cooling device (a base) 103 is provided on the bottom surface side of the respective semiconductor devices 101a to 101c with sheet-like resin layers (resin sheets) 102a to 102c interposed.

The resin sheets 102a to 102c have a function of insulating and bonding the respective semiconductor devices 101a to 101c and the cooling device 103 to each other while releasing heat from the semiconductor devices 101a to 101c to the cooling device 103. The resin sheets 102a to 102c as used herein can include epoxy resin, for example. The cooling device 103 as used herein can include material such as copper (Cu), aluminum (Al), composite material (AlSiC) of Al and silicon carbide, and composite material (MgSiC) of magnesium (Mg) and silicon carbide.

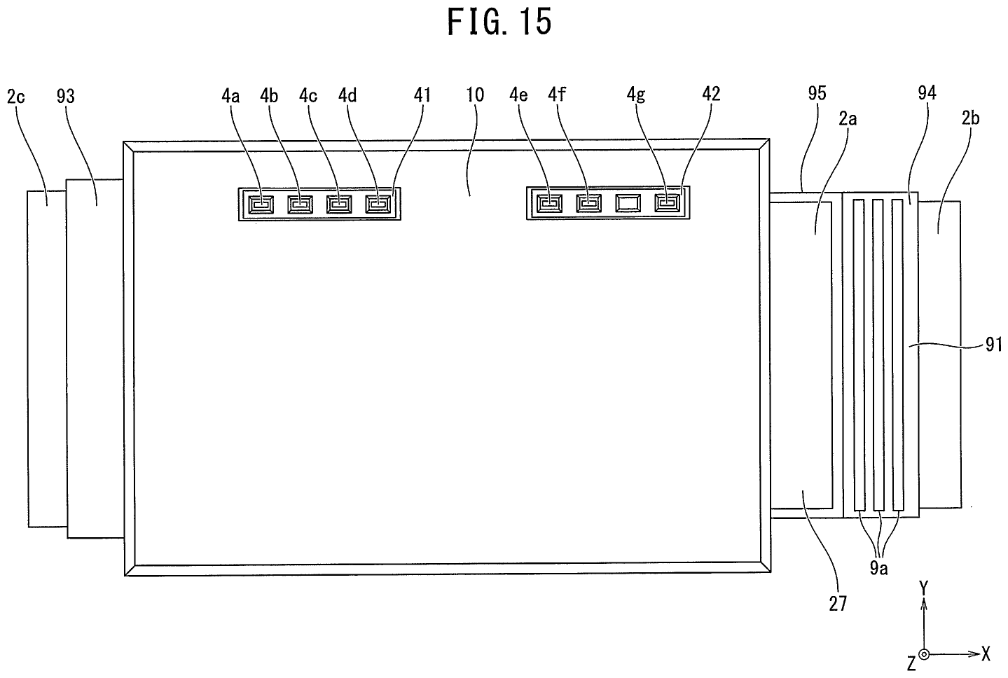

FIG. 14 is an equivalent circuit diagram of the semiconductor device according to the first embodiment. As illustrated in FIG. 14, the semiconductor device according to the first embodiment implements a part of a three-phase bridge circuit. A drain electrode of a transistor T1 on the upper-arm side is connected to a positive electrode terminal P, and a source electrode of a transistor T2 on the lower-arm side is connected to a negative electrode terminal N. A source electrode of the transistor T1 and a drain electrode of the transistor T2 are connected to an output terminal U and an auxiliary source terminal S1. An auxiliary source terminal S2 is connected to the source electrode of the transistor T2. Gate control terminals G1 and G2 are connected to gate electrodes of the respective transistors T1 and T2. Body diodes D1 and D2 each serving as a freewheeling diode (FWD) are internally connected in antiparallel to the transistors T1 and T2.

The output terminal U, the positive electrode terminal P, and the negative electrode terminal N illustrated in FIG. 14 respectively correspond to the output terminal 2c, the positive electrode terminal 2b, and the negative electrode terminal 2a illustrated in FIG. 1 and FIG. 2. The transistor T1 and the body diode D1 illustrated in FIG. 14 correspond to the semiconductor chips 3g to 3l illustrated in FIG. 5 and FIG. 6. The transistor T2 and the body diode D2 illustrated in FIG. 14 correspond to the semiconductor chips 3a to 3f illustrated in FIG. 5 and FIG. 6. The gate control terminals G1 and G2 illustrated in FIG. 14 correspond to the control terminals 4a and 4e illustrated in FIG. 1 and FIG. 2. The auxiliary source terminals S1 and S2 illustrated in FIG. 14 correspond to the control terminals 4b and 4f illustrated in FIG. 1 and FIG. 2.

### <Method of Manufacturing Semiconductor Device>

An example of a method of manufacturing (assembling) the semiconductor device according to the first embodiment is described below.

First, the positive electrode terminal 2b, the output terminal 2c, and the insulating members 91 to 93 are formed integrally with each other by transfer molding with a metal die, for example, so as to form the integrated structure body (2b, 2c, 91 to 93) as illustrated in FIG. 7. The positive electrode terminal 2b and the output terminal 2c are formed integrally with the tie-bar wires 2x and 2y.

In addition, the negative electrode terminal 2a, the conductive member 6, and the insulating member 8 are formed integrally with each other by transfer molding with a metal die, for example, while the insulating member 60 is interposed between the conductive member 6 and the insulating member 8 so as to prepare the integrated structure body (2a, 6, 8), as illustrated in FIG. 8.

As illustrated in FIG. 5, the respective members such as the semiconductor chips 3a to 3f, the printed board (11, 12a to 12d), the temperature detection chip 5, the pads 15, 16, 17a, and 17b, the sleeves 5a to 5d, and the like are bonded onto the respective top surfaces of the conductive plates 10a and 10b of the insulated circuit substrate 1a via bonding material such as solder, a conductive adhesive, and sintered material. Further, the semiconductor chips 3a to 3f, the printed board (11, 12a to 12d), and the temperature detection chip 5 are electrically connected to each other via the bonding wires 71a to 71f, 72a to 72f, 73a, and 73b.

Further, as illustrated in FIG. 5, the semiconductor chips 3g to 3l, the printed board (13, 14a, 14b), the pad 18, the sleeves 5e to 5g, and the like are bonded onto the top surface of the conductive plate 10c of the insulated circuit substrate 1b via bonding material such as solder, a conductive adhesive, and sintered material. Further, the semiconductor chips 3g to 3l and the printed board (13, 14a, 14b) are electrically connected to each other via the bonding wires 71g to 71l and 72g to 72l.

Next, the respective top surface sides of the insulated circuit substrates 1a and 1b and the integrated structure body (2b, 2c, 91 to 93) are positioned to each other, as illustrated in FIG. 6, and the output terminal 2c of the integrated structure body (2b, 2c, 91 to 93) is bonded to the pads 17a and 17b via bonding material such as solder, a conductive adhesive, and sintered material. Further, the positive electrode terminal 2b of the integrated structure body (2b, 2c, 91 to 93) is bonded to the pad 18 via bonding material such as solder, a conductive adhesive, and sintered material. Although not illustrated in FIG. 6, the tie-bar wires 2x and 2y are connected to the positive electrode terminal 2b and the output terminal 2c.

Next, the control terminals 4a to 4d supported by the insulating member 41 and the control terminals 4e to 4g supported by the insulating member 42 are positioned on the top surface side of the openings 92a to 92g of the insulating member 92 of the integrated structure body (2b, 2c, 91 to 93) so that the lower parts of the control terminals 4a to 4g are inserted to be positioned to the corresponding openings 92a to 92g. The lower parts of the control terminals 4a to 4g are further press-fitted and fixed to the sleeves 5a to 5g.

Nest, as illustrated in FIG. 3, the integrated structure body (2a, 6, 8) is positioned on the top surface side of the respective insulated circuit substrates 1a and 1b and the integrated structure body (2b, 2c, 91 to 93), and the terminal part 27 of the negative electrode terminal 2a of the integrated structure body (2a, 6, 8) is placed on the top surface side of the covering part 94 of the insulating member 91. The negative electrode terminal 2a at this point is positioned by the frame part 95 of the insulating member 91. Further, the engagement parts 96a and 96b of the insulating member 91 engage with the engagement parts 25a and 25b of the negative electrode terminal 2a, so that the negative electrode terminal 2a is positioned.

Further, the pad bonding part 29 of the negative electrode terminal 2a is bonded to the pad 16 via bonding material such as solder, a conductive adhesive, and sintered material. The chip bonding parts 21a to 21f of the negative electrode terminal 2a are bonded to the source electrodes 31a to 31f of the semiconductor chips 3a to 3f via bonding material such as solder, a conductive adhesive, and sintered material. The pad bonding part 61 of the conductive member 6 is bonded to the pad 16 via bonding material such as solder, a conductive adhesive, and sintered material. The chip bonding parts 61a to 61f of the conductive member 6 are bonded to the source electrodes 31g to 31l of the semiconductor chips 3g to 3l via bonding material such as solder, a conductive adhesive, and sintered material.

Next, the semiconductor chips 3a to 3l are sealed with the sealing resin 10 by transfer molding, and the negative electrode terminal 2a, the positive electrode terminal 2b, the output terminal 2c, and the respective control terminals 4a to 4g are partly sealed with the sealing resin 10 by transfer molding, as illustrated in FIG. 1. Further, as illustrated in FIG. 2, the tie-bar wires 2x and 2y are cut out so that the positive electrode terminal 2b and the output terminal 2c are separated from each other. The semiconductor device according to the first embodiment is thus completed.

The semiconductor device according to the first embodiment has the configuration having the integrated structure body (2a, 6, 8) including the negative electrode terminal 2a, the conductive member 6, and the insulating member 8 formed integrally with each other so as to implement a three-dimensionally-wired main wiring circuit, while separately implementing the control wiring circuit including the printed board (11, 12a to 12d) and the printed board (13, 14a, 14b). This configuration can decrease the wiring area, so as to achieve a reduction in chip size and cost and also ensure the low inductance properties, as compared with a conventional semiconductor device in which semiconductor chips are mounted on a circuit pattern of an insulated circuit substrate so that the semiconductor chips and the circuit pattern of the insulated circuit substrate are electrically connected together via lead frames and bonding wires. Further, the semiconductor device according to the first embodiment having the configuration as described above does not need to use a casing for surrounding the insulated circuit substrate to inject resin by potting to seal the insulated circuit substrate, so as to achieve a reduction in space, a decrease in the number of the manufacturing steps, and a reduction in cost, as compared with the conventional semiconductor device using such a casing.

Further, the semiconductor device according to the first embodiment having the configuration of using the integrated structure body (2b, 2c, 91 to 93) in which the positive electrode terminal 2b, the output terminal 2c, and the insulating members 91 to 93 are integrated together, can keep the insulation between the positive electrode terminal 2b and the negative electrode terminal 2a and the insulation with ground. In addition, the provision of the positive electrode terminal 2b and the output terminal 2c by use of the tie-bar wires 2x and 2y can ensure the accuracy of positioning the positive electrode terminal 2b and the output terminal 2c without using any jigs for internal wiring.

Further, the semiconductor device according to the first embodiment has the structure including the insulating member 91 provided with the engagement parts 96a and 96b and the negative electrode terminal 2a provided with the engagement parts 25a and 25b so as to be engaged together. This structure can ensure the accuracy of positioning the positive electrode terminal 2b and the output terminal 2c without using any jigs for internal wiring, so that the positive electrode terminal 2b and the negative electrode terminal 2a can be arranged adjacent to each other (laminated together). The manufacturing performance by the transfer molding thus can be improved, so as to achieve a low-inductance structure capable of making the maximum use of the properties of the SiC chips and the like.

Further, the semiconductor device according to the first embodiment having the structure in which the insulating member 92 of the integrated structure body (2b, 2c, 91 to 93) is provided with the openings 92a to 92g can facilitate the positioning of the control terminals 4a to 4g, so as to improve the accuracy of positioning the control terminals 4a to 4g.

### Second Embodiment

FIG. 15 is a plan view illustrating a semiconductor device according to a second embodiment. The semiconductor device according to the second embodiment differs from the semiconductor device according to the first embodiment in that the insulating member 91 is provided with slits (grooves) 9a on the top surface side, as illustrated in FIG. 15. The specifications of the slits 9a, such as the number, the length, the width, and the depth, can be determined as appropriate. The other configurations of the semiconductor device according to the second embodiment are substantially the same as those of the semiconductor device according to the first embodiment, and overlapping explanations are not repeated below.

The semiconductor device according to the second embodiment further provided with the slits 9a on the top surface side of the insulating member 91 can ensure the insulating distance between the negative electrode terminal 2a and the positive electrode terminal 2b more reliably.

### Third Embodiment

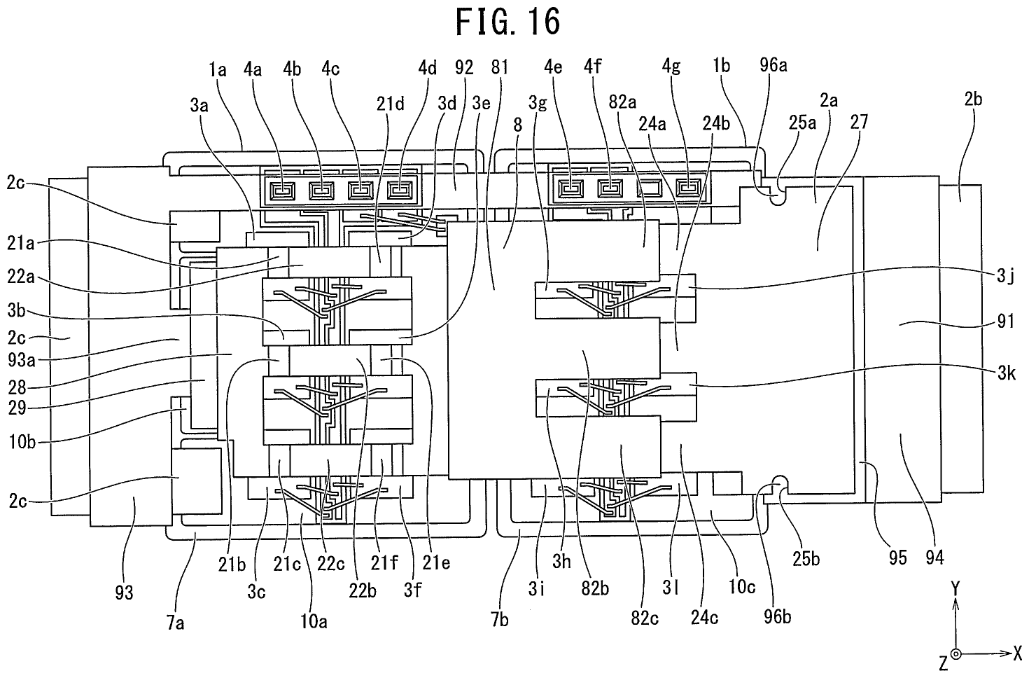

FIG. 16 is a plan view illustrating a semiconductor device according to a third embodiment while omitting the illustration of the sealing resin 10. The semiconductor device according to the third embodiment differs from the semiconductor device according to the first embodiment in that the insulating member 93 is provided with a fixing part (a projection) 93a for fixing the negative electrode terminal 2a, as illustrated in FIG. 16. The end part of the fixing part 93a is arranged to be located at a position so as to be in contact with the pad bonding part 29 of the negative electrode terminal 2a. The position and the shape of the fixing part for fixing the negative electrode terminal 2a are not limited to the case as described above, and may be determined so as to fix the negative electrode terminal 2a appropriately. The other configurations of the semiconductor device according to the third embodiment are substantially the same as those of the semiconductor device according to the first embodiment, and overlapping explanations are not repeated below.

The semiconductor device according to the third embodiment, which is further provided with the fixing part 93a in the insulating member 93, can fix (position) the negative electrode terminal 2a at the end part on the opposite side of the end at which the negative electrode terminal 2a is arranged adjacent to the positive electrode terminal 2b.

### Other Embodiments

While the present disclosure has been described above by reference to the first to third embodiments, it should be understood that the present disclosure is not intended to be limited to the descriptions and the drawings composing part of this disclosure. Various alternative embodiments, examples, and technical applications will be apparent to those skilled in the art according to this disclosure.

For example, while the first to third embodiments have been illustrated with the case in which the positive electrode terminal 2b is covered with the insulating member 91, and the negative electrode terminal 2a is arranged adjacent to the positive electrode terminal 2b on the top surface side with the insulating member 91 interposed, the positional relation between the positive electrode terminal 2b and the negative electrode terminal 2a may be reversed. Namely, the negative electrode terminal 2a may be covered with the insulating member 91, and the positive electrode terminal 2b may be arranged on the top surface side of the negative electrode terminal 2a with the insulating member 91 interposed.

Further, the configurations disclosed in the embodiments may be combined as appropriate within a range that does not contradict with the scope of the respective embodiments. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. A semiconductor device comprising:
an insulated circuit substrate including an insulating plate and a conductive plate provided on a top surface side of the insulating plate;
a semiconductor chip provided on a top surface side of the conductive plate;
a first external terminal electrically connected to the semiconductor chip;
a first insulating member including a covering part covering a part of the first external terminal and a first engagement part provided on a top surface side of the covering part;
a second external terminal electrically connected to the semiconductor chip, provided on a top surface side of the first external terminal with the covering part interposed, and including a second engagement part so as to engage with the first engagement part; and
a sealing resin provided to seal the semiconductor chip and partly seal each of the first external terminal, the first insulating member, and the second external terminal.

2. The semiconductor device of claim 1, wherein:
the first engagement part is a projecting part; and
the second engagement part is a recessed part.

3. The semiconductor device of claim 1, wherein the first engagement part and the second engagement part are covered with the sealing resin.

4. The semiconductor device of claim 1, wherein the first insulating member includes a frame part surrounding a part of a side surface of the second external terminal.

5. The semiconductor device of claim 1, further comprising:
a third external terminal electrically connected to the semiconductor chip and arranged separately from the first external terminal and the second external terminal; and
a second insulating member provided to cover a part of the third external terminal.

6. The semiconductor device of claim 5, further comprising a third insulating member provided between the first insulating member and the second insulating member so as to be integrated together.

7. The semiconductor device of claim 6, further comprising a control terminal electrically connected to the semiconductor chip,
wherein the third insulating member has an opening for positioning the control terminal.

8. The semiconductor device of claim 1, wherein the covering part is provided with a slit on the top surface side.

9. The semiconductor device of claim 1, wherein the second insulating member is provided with a fixing part for fixing the second external terminal.
